(19) United States
(12) Patent Application Publication
(10) Pub. No.: US 2006/0208929 A1
(43) Pub. Date: Sep. 21, 2006

(54) High definition multimedia interface device and output control method thereof

(75) Inventor: Song Ki Cho, Seoul (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/369,881

(22) Filed: Mar. 8, 2006

(30) Foreign Application Priority Data
Mar. 16, 2005 (KR) 2005-21918

(51) Int. Cl. H03M 7/00; H04N 11/00; H04N 7/01

(52) U.S. Cl. 341/50; 348/441; 386/37

(57) ABSTRACT

A high definition multimedia interface (HDMI) device and an output control method thereof are disclosed. The HDMI device includes a moving picture experts group (MPEG) decoder for decoding an MPEG stream, and an HDMI transmitter for transmitting an output of the MPEG decoder to a display device. The method comprises determining whether an HDMI cable has been connected between the HDMI device and the display device, and inhibiting digital data from being output from the MPEG decoder to the HDMI transmitter if the HDMI cable has not been connected.

### CROSS-REFERENCE TO RELATED APPLICATION

This application claims the benefit under 35 U.S.C. §119(a) of Korean Patent Application No. 2005-21918, filed on Mar. 16, 2005 in the Korean Intellectual Property Office, the entire disclosure of which is hereby incorporated by reference.

### BACKGROUND OF THE INVENTION

1. Field of the Invention

The present invention relates to a high definition multimedia interface (HDMI) device and an output control method thereof. More particularly, the present invention relates to an apparatus and method in which digital data is output from the HDMI device to a display device only when a HDMI cable is connected there between.

2. Description of the Related Art

Recently, digital versatile discs (DVDs) have been introduced as a recording media that records and reproduces high quality video. Additionally, digital televisions (TVs) have been developed that display high resolution video. By virtue of their proliferation in the market, an increasing number of consumers have interconnected and used various DVD devices (for example, a DVD player, a DVD recorder, and so on) that record and/or reproduce video with DVDs and digital TVs. Accordingly, the digital visual interface (DVI) and high definition multimedia interface (HDMI) have been standardized as a digital interface for the transfer of data between a DVD device and a digital TV.

Devices that transfer video and audio data to display devices, such as digital TVs, using HDMI are typically called HDMI devices. Examples of HDMI devices include set-top boxes, video tape recorders (VTRs), game machines, and various DVD devices. A conventional HDMI device is the DVD device disclosed in Korean Patent Laid-open Publication No. 10-2004-0071247. This DVD device comprises a moving picture experts group (MPEG)-2 decoder for decoding a MPEG-2 stream, a transmitter for encoding data to be transmitted over a plurality of channels, and a microcontroller for controlling the transmitter and MPEG-2 decoder.

This conventional HDMI device is adapted to encode video and audio data that is output from the MPEG-2 decoder using transition minimized differential signaling (TMDS). Further, the conventional HDMI device is adapted to transmit the encoded data to a display device using a HDMI link.

However, the above-mentioned conventional HDMI device has a drawback in that there is an increase in electromagnetic compatibility (EMC) caused by noise that occurs when the HDMI device is powered on and a HDMI link between the HDMI device and the display device is not being used. The source of the noise is the digital video and audio data being output from the MPEG-2 decoder to the transmitter.

EMC is an umbrella term that brings together two concepts, electromagnetic interference (EMI) and electromagnetic susceptibility (EMS). EMI is the level of radio frequency (RF) interference at a device caused by the operation of another device. EMS is the level of resistance a device has to all ambient RF energy (static electricity, surge, and so on).

Accordingly, there is a need for an improved HDMI device including an output control method that does not increase electromagnetic compatibility (EMC) of a HDMI device when the HDMI device is powered on and is not using a HDMI link.

### SUMMARY OF THE INVENTION

An aspect of the present invention is to address at least the above problems and/or disadvantages and to provide at least the advantages described below. Accordingly, an aspect of the present invention is to provide a method for controlling an output of a high definition multimedia interface (HDMI) device, the HDMI device including a moving picture experts group (MPEG) decoder for decoding an MPEG stream, and an HDMI transmitter for transmitting an output of the MPEG decoder to a display device. The method comprises determining whether a signal transmission line has been connected between the HDMI device and the display device and inhibiting digital data from being output from the MPEG decoder to the HDMI transmitter if the signal transmission line has not been connected.

Preferably, the method further comprises allowing the digital data to be outputted from the MPEG decoder to the HDMI transmitter if the signal transmission line has been connected.

The signal transmission line may include a plurality of channels for transmitting the digital data.

The determination may be performed using a signal on a hot plug detect (HPD) line connected between the HDMI device and the display device.

Preferably, the determination includes determining the HDMI device and the display device to have been interconnected via the signal transmission line if the signal on the HPD line is high, and the HDMI device and the display device not to have been interconnected via the signal transmission line if the signal on the HPD line is low.

The digital data may include video data, a horizontal synchronous signal, a vertical synchronous signal, and audio data.

In accordance with another aspect of the invention, there is provided an HDMI device comprising an MPEG decoder for decoding an MPEG stream, an HDMI transmitter for transmitting an output of the MPEG decoder to a display device using a signal transmission line, and a controller for inhibiting digital data from being output from the MPEG decoder to the HDMI transmitter if the HDMI device and the display device are not interconnected via the signal transmission line.

The MPEG decoder may include an output control block for controlling the output of the digital data in response to a control command from the controller.

The digital data may include video data, a horizontal synchronous signal, a vertical synchronous signal, and audio data, and the output control block may ground the video data, horizontal synchronous signal, vertical synchronous signal and audio data so as to inhibit the digital data from being output.

The signal transmission line may include a plurality of channels for transmitting the digital data.

The controller may determine whether the HDMI device and the display device have been interconnected via the signal transmission line, using a signal on an HPD line connected between the HDMI transmitter and the display device.

Other objects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other objects, features, and advantages of certain embodiments of the present invention will be more apparent from the following description taken in conjunction with the accompanying drawings, in which:

FIG. 1 is a view showing a connection between a DVD player, an exemplary HDMI device according to an embodiment of the present invention, and a digital TV via an HDMI cable;

FIG. 2 is a detailed block diagram of the DVD player and digital TV of FIG. 1;

FIG. 3 is a block diagram illustrating, in detail, various signals output from an MPEG-2 decoder in the DVD player of FIG. 2; and

FIG. 4 is a flow chart illustrating a method for controlling the output of the MPEG-2 decoder in the DVD player, an exemplary HDMI device according to an embodiment of the present invention.

Throughout the drawings, the same drawing reference numerals will be understood to refer to the same elements, features, and structures.

### DETAILED DESCRIPTION OF EXEMPLARY EMBODIMENTS

The matters defined in the description such as a detailed construction and elements are provided to assist in a comprehensive understanding of the embodiments of the invention. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

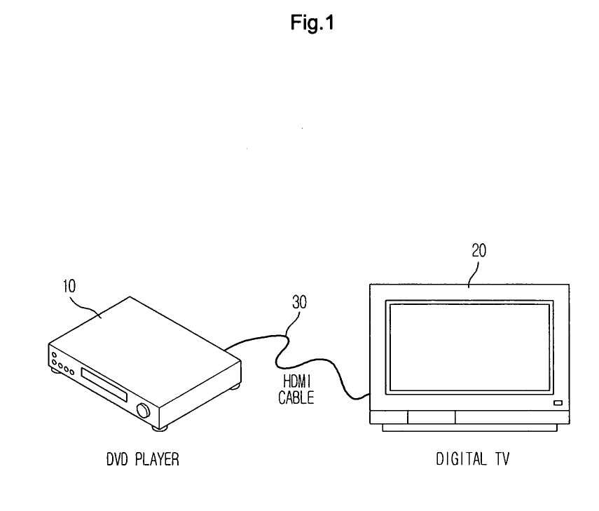

FIG. 1 shows a connection between a DVD player 10, an exemplary HDMI device (or source device), and a digital TV 20 via an HDMI cable 30. In other words, the DVD player 10 is HDMI-linked with the digital TV 20 via the HDMI cable 30.

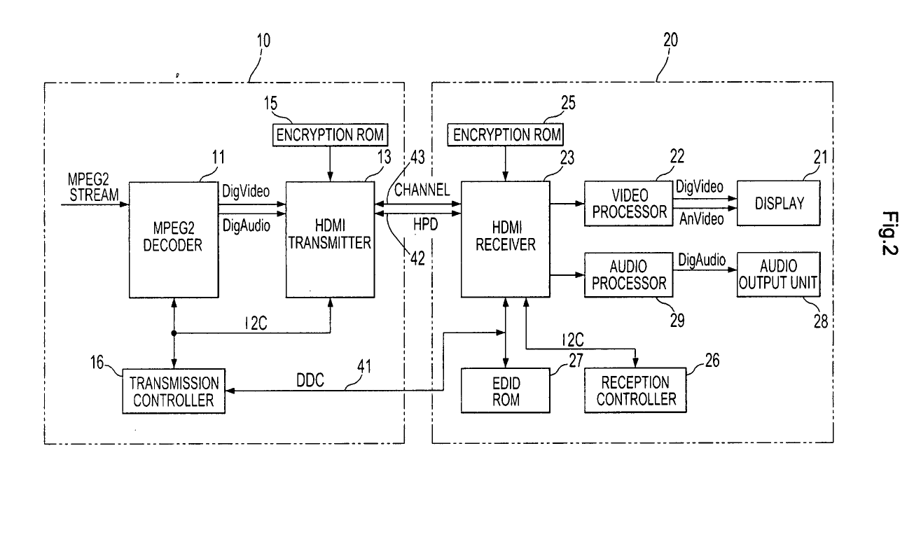

FIG. 2 shows a DVD player 10 comprising an MPEG-2 decoder 11, an HDMI transmitter 13, an encryption read only memory (ROM) 15, and a transmission controller 16. The MPEG-2 decoder 11 is adapted to receive and decode an MPEG-2 stream reproduced from a DVD drive (not shown) or delivered from a set-top box (not shown). The HDMI transmitter 13 is adapted to receive transition minimized differential signaling (TMDS)-encoded digital data output from the MPEG-2 decoder 11 and transmit the encoded digital data to the digital TV 20 through the HDMI cable 30.

The encryption ROM 15 is adapted to store a key value and an identification bit which are used for High bandwidth Digital Content Protection (HDCP) encryption of the data to be transmitted to the digital TV 20. The transmission controller 16 is adapted to control the MPEG-2 decoder 11 and the HDMI transmitter 13. The transmission controller 16 is further adapted to perform 12C communication with the HDMI transmitter 13.

The digital TV 20 of FIG. 2 is an exemplary display device (or Sync device), and includes an HDMI receiver 23, a video processor 22, a display 21, an audio processor 29, an audio output unit 28, an extended display identification data (EDID) ROM 27, an encryption ROM 25 and a reception controller 26. The HDMI receiver 23 is adapted to receive and TMDS-decode the digital data transmitted from the HDMI transmitter 13. The decryption ROM 25 is adapted to store a key value and an identification bit which are used for High bandwidth Digital Content Protection (HDCP) decryption of the data to be received from the DVD player 10. The video processor 22 is adapted to process digital video data sent from the HDMI receiver 23 and to send the resulting digital video data DigVideo or analog video data AnVideo to the display 21. The audio processor 29 is adapted to process digital audio data sent from the HDMI receiver 23 and to send the resulting digital audio data DigAudio to the audio output unit 28. The display 21 is adapted to output the video data from the video processor 22 as video viewable by the user. The audio output unit 28 is adapted to output the audio data from the audio processor 29 as audible sound.

The EDID ROM 27 is adapted to store extended display identification data (EDID), which is display characteristic information data containing a manufacturer's name, specifications, supported resolutions, color formats, and so on. This EDID is stored in the EDID ROM 27 at the time of the digital TV's manufacturing. The EDID ROM 27 is also connected with the transmission controller 16 via a display data channel (DDC) line 41, so that the transmission controller 16 can read the EDID from the EDID ROM 27 over the DDC line 41. The reception controller 26 is adapted to control the above components of the digital TV 20 and perform 12C communication with the HDMI receiver 23.

The HDMI transmitter 13 and the HDMI receiver 23 are interconnected via the HDMI cable 30, which includes a plurality of channels 43 and a hot plug detect (HPD) line 42. The plurality of channels 43 are signal lines for transmission of digital video and digital audio data, and include three data transmission channels CH0, CH1 and CH2, and one clock channel CHC. The HPD line 42 is provided to enable the transmission controller 16 to determine whether the DVD player 10 and the digital TV 20 are interconnected via the HDMI cable 30. If the digital TV 20 is connected with the DVD player 10 via the HDMI cable 30, a high signal is applied to the HPD line 42 to indicate the digital TV's 20 presence. On the contrary, if the digital TV 20 is not connected with the DVD player 10 via the HDMI cable 30, typically a low signal is applied to the HPD line 42. The transmission controller 16 checks a voltage on the HPD line 42 in order to determine if the digital TV 20 is HDMI-linked with the DVD player 10. Of course any suitable signal, including a current or frequency, could be used on the HPD line 42 to indicate the digital TV's 20 presence. Preferably, the digital TV 20 is considered HDMI-linked with the DVD player 10 if the voltage on the HPD line 42 is high, such as 2.2-5.05V. Further, the digital TV 20 is considered not HDMI-linked with the DVD player if the voltage on the HPD line 42 is low, such as 0-0.4V.

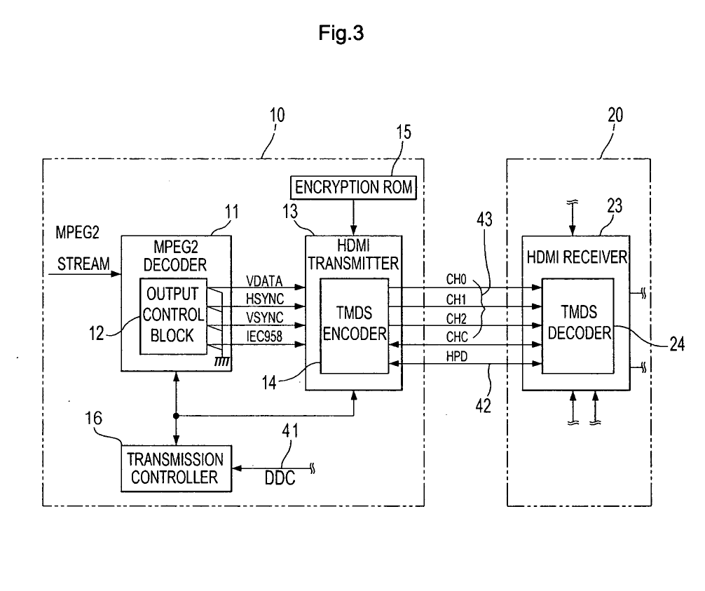

An output control block 12 is provided in the MPEG-2 decoder 11, as shown in FIG. 3, to control the output of the MPEG-2 decoder 11. The output control block 12 is adapted to control the output of the MPEG-2 decoder 11 in response to a control command from the transmission controller 16. The digital data which is output from the MPEG-2 decoder 11 to the HDMI transmitter 13 includes video data VDATA, such as RGB data, a horizontal synchronous signal HSYNC, a vertical synchronous signal VSYNC, and audio data IEC958. The output control block 12, under the control of the transmission controller 16, either sends digital data output from the MPEG-2 decoder to the HDMI transmitter 13 or grounds the signal lines so that there is no output signal.

The HDMI transmitter 13 includes a TMDS encoder 14 for TMDS-encoding the digital data output from the MPEG-2 decoder 11. The HDMI receiver 23 includes a TMDS decoder 24 for TMDS-decoding the digital data encoded and transmitted by the HDMI transmitter 13.

Preferably, the TMDS encoder 14 converts parallel 8-bit 3-channel VDATA, HSYNC and VSYNC video data into serial 10-bit 3-channel video data, and parallel 4-bit audio data IEC958 into serial 10-bit audio data, respectively. The converted digital data is then transmitted to the HDMI receiver 23 over the respective channels 43 of the HDMI cable 30. Preferably, the TMDS decoder 24 restores the serial 10-bit video data and serial 10-bit audio data transmitted over the respective channels 43 back into parallel 8-bit video data and parallel 4-bit audio data, respectively.

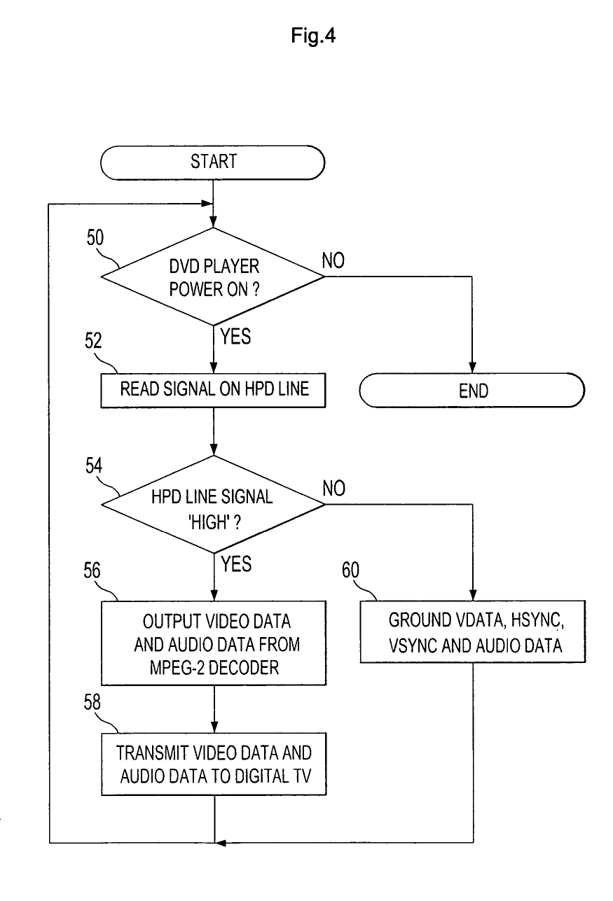

A method for controlling the output of the DVD player, an exemplary HDMI device, according to an embodiment of the present invention, will hereinafter be described with reference to FIG. 4. In an embodiment of the present invention, when the DVD player 10 is powered on, and is not transmitting digital data to a display device, such as the digital TV 20, the data output from the MPEG-2 decoder 11 is inhibited to reduce EMC. To this end, the transmission controller 16 determines whether the DVD player 10 is powered on (50), and then proceeds to the next step only when the DVD player 10 is powered on.

If it is determined at step 50 that the DVD player 10 is powered on, the transmission controller 16 performs I2C communication with the HDMI transmitter 13 to check a signal on the HPD line 42 (or a voltage on the HPD line 42) so as to determine whether the DVD player 10 and the digital TV 20 have been interconnected via the HDMI cable 30 (52). The transmission controller 16 then determines whether the signal on the HPD line 42 is ‘high’ (54). Preferably, the voltage on the HPD line 42 is considered ‘high’ when the voltage is about 2.4-5.05V.

When the signal on the HPD line 42 is ‘high’, the transmission controller 16 recognizes that the DVD player 10 can transmit digital data to the digital TV 20 because it has been connected to the digital TV 20 via the HDMI cable 30. Accordingly, the transmission controller 16 sends a control command to the output control block 12 via a 12C communication therewith such that the MPEG-2 decoder 11 outputs video data VDATA, a horizontal synchronous signal HSYNC, a vertical synchronous signal VSYNC, and audio data IEC958 (56). If these signals are output from the MPEG-2 decoder 11, the HDMI transmitter 13 TMDS-encodes those signals and transmits the resulting signals to the HDMI receiver 23 (58).

On the other hand, if it is determined at step 54 that the signal on the HPD line 42 is ‘low’, the transmission controller 16 recognizes that the DVD player 10 and the digital TV 20 have not been interconnected via the HDMI cable 30. Preferably, a voltage on HPD line 42 is considered ‘low’ when the voltage is about 0-0.4V. Accordingly, the transmission controller 16 sends a control command to the output control block 12 via a 12C communication therewith such that the output control block 12 grounds video data VDATA, a horizontal synchronous signal HSYNC, a vertical synchronous signal VSYNC, and audio data IEC958 (60).

Although the VDATA video data and the IEC958 audio data are shown in FIG. 3 to be separated from each other for the convenience of description, it will be understood that the audio data IEC958 is typically interleaved in the video data VDATA. In this regard, when the video data VDATA is grounded, the audio data IEC958 is grounded as well. If the various digital data lines are grounded in this mainer, the MPEG-2 decoder 11 is prevented from outputting digital data and thus permits DVD player 10 to output only analog signals, such as a composite signal, an S-VIDEO signal, or a component signal. By only outputting analog signals, a reduction in the occurrence of noise results.

Although the DVD player has been disclosed as an example of a HDMI device, the present invention is applicable to all devices with HDMI outputs, such as a set-top box, a VTR or a game machine.

As is apparent from the above description, according to an embodiment of the present invention, an MPEG-2 decoder outputs digital data only when an HDMI device (such as, a source device) and a display device (such as, a Sync device) are interconnected via an HDMI cable. It is therefore possible to reduce EMC.

While the invention has been shown and described with reference to certain embodiments thereof, it will be understood by those skilled in the art that various changes in form and details may be made therein without departing from the spirit and scope of the invention as defined by the appended claims.

What is claimed is:

1. A method for controlling an output of a high definition multimedia interface (HDMI) device, the HDMI device including a moving picture experts group (MPEG) decoder for decoding an MPEG stream, and an HDMI transmitter for transmitting an output of the MPEG decoder to a display device, the method comprising:
determining whether a signal transmission line has been connected between the HDMI device and the display device; and
inhibiting digital data from being output from the MPEG decoder to the HDMI transmitter if it has been determined that the signal transmission line has not been connected.

2. The method as set forth in claim 1, further comprising allowing the digital data to be output from the MPEG decoder to the HDMI transmitter if it has been determined that the signal transmission line has been connected.

3. The method as set forth in claim 1, wherein the signal transmission line includes a plurality of channels for transmitting the digital data.

4. The method as set forth in claim 1, wherein the determining is performed using a signal on a hot plug detect (HPD) line connected between the HDMI device and the display device.

5. The method as set forth in claim 4, wherein the determining includes determining the HDMI device and the display device to have been interconnected via the signal transmission line if the signal on the HPD line is high, and the HDMI device and the display device not to have been interconnected via the signal transmission line if the signal on the HPD line is low.

6. The method as set forth in claim 5, wherein the signal on the HPD line is high if the signal is about 2.4-5.05 volts.

7. The method as set forth in claim 5, wherein the signal on the HPD line is low if the signal is about 0-0.4 volts.

8. The method as set forth in claim 1, wherein the digital data includes video data, a horizontal synchronous signal, a vertical synchronous signal, and audio data.

9. The method as set forth in claim 1, wherein the HDMI device is one of a DVD player, DVD recorder, set-top box, video tape recorder and game machine.

10. The method as set forth in claim 1, wherein the signal transmission line is comprised by a HDMI cable.

11. An HDMI device comprising:
an MPEG decoder for decoding an MPEG stream;
an HDMI transmitter for transmitting an output of the MPEG decoder to a display device using a signal transmission line; and
a controller for inhibiting digital data from being output from the MPEG decoder to the HDMI transmitter if the HDMI device and the display device are not interconnected via the signal transmission line.

12. The HDMI device as set forth in claim 11, wherein the MPEG decoder includes an output control block for controlling the output of the digital data in response to a control command from the controller.

13. The HDMI device as set forth in claim 12, wherein the digital data includes video data, a horizontal synchronous signal, a vertical synchronous signal, and audio data,
wherein the output control block is adapted to ground signal lines used to output the video data, horizontal synchronous signal, vertical synchronous signal and audio data so as to inhibit the digital data from being output.

14. The HDMI device as set forth in claim 11, wherein the signal transmission line includes a plurality of channels for transmitting the digital data.

15. The HDMI device as set forth in claim 11, wherein the controller is adapted to determine whether the HDMI device and the display device have been interconnected via the signal transmission line, using a signal on an HPD line connected between the HDMI transmitter and the display device.

16. The method as set forth in claim 15, wherein the controller is adapted to determine that the HDMI device and the display device have been interconnected when the signal on an HPD line is high, and determine that the HDMI device and the display device are not interconnected when the signal on an HPD line is low.

17. The method as set forth in claim 16, wherein the signal on the HPD line is high if the signal is about 2.4-5.05 volts.

18. The method as set forth in claim 16, wherein the signal on the HPD line is low if the signal is about 0-0.4 volts.

19. The method as set forth in claim 11, wherein the HDMI device is one of a DVD player, DVD recorder, set-top box, video tape recorder and game machine.

20. The method as set forth in claim 1, wherein the signal transmission line is comprised by a HDMI cable.
